(19) United States
(12) Patent Application Publication
(10) Pub. No.: US 2024/0258487 A1
(43) Pub. Date: Aug. 1, 2024

(54) DISPLAY DEVICE AND METHOD FOR MANUFACTURING THE SAME

(71) Applicant: LG Display Co., Ltd., Seoul (KR)

(72) Inventors: Sunghwan YOON, Seoul (KR); Yuseop SHIN, Bucheon-si (KR); Dongseok LEE, Bucheon-si (KR); Jusang RHIM, Seoul (KR); Minjae KANG, Seoul (KR); Rokhee LEE, Seoul (KR)

(21) Appl. No.: 18/424,449

(22) Filed: Jan. 26, 2024

(30) Foreign Application Priority Data
Jan. 31, 2023 (KR) 10-2023-0013297

(51) Int. Cl. H01L 33/62; H01L 25/16; H01L 33/58

(52) U.S. Cl. CPC H01L 33/62; H01L 25/167; H01L 33/58; H01L 2933/0066

(57) ABSTRACT

Disclosed are a display device and a method for manufacturing the same. The display device includes a first substrate including a thin-film transistor. The display device includes a second substrate including a light-emitting element. The display device includes a bonding pad disposed between the first substrate and the second substrate. The bonding pad bonds the first substrate and the second substrate to each other and electrically connects the thin-film transistor of the first substrate and the light-emitting element of the second substrate to each other.

### CROSS-REFERENCE TO RELATED APPLICATION

This application claims priority from Korean Patent Application No. 10-2023-0013297 filed on Jan. 31, 2023, in the Korean Intellectual Property Office, and all the benefits accruing therefrom under 35 U.S.C. 119, the contents of which in its entirety are herein incorporated by reference.

### TECHNICAL FIELD

The present disclosure relates to a display device, and more specifically, to a display device including a self-assembly substrate, and a method for manufacturing the same.

### DESCRIPTION OF THE RELATED ART

A display device is applied to various electronic devices such as TVs, mobile phones, laptops, and tablets. To this end, research to develop thinning, lightening, and low power consumption of the display device is continuing.

Among display devices, a light-emitting display device has a light-emitting element or a light source built therein and displays information using light generated from the built-in light-emitting element or light source. A display device including a self-light-emitting element may be implemented to be thinner than a display device with the built-in light source, and may be implemented as a flexible display device that may be folded, bent, or rolled.

The display device having the self-light-emitting element may include, for example, an organic light-emitting display device (OLED) including a light-emitting layer made of an organic material, or a micro-LED display device (micro light-emitting diode display device) including a light-emitting layer made of an inorganic material. In this regard, the organic light-emitting display device does not require a separate light source. However, due to material characteristics of the organic material that is vulnerable to moisture and oxygen, a defective pixel easily occurs in the organic light-emitting display device due to an external environment. On the contrary, the micro-LED display device includes the light-emitting layer made of the inorganic material that is resistant to moisture and oxygen and thus is not affected by the external environment and thus has high reliability and has a long lifespan compared to the organic light-emitting display device.

### BRIEF SUMMARY

Various embodiments of the present disclosure provide a display device in which a substrate including thin-film transistors is bonded to a substrate including a light-emitting element (for example, a self-assembly substrate with which a plurality of light-emitting elements are assembled in an aligned manner).

Furthermore, various embodiments of the present disclosure provide a method for manufacturing a display device in which a package substrate including thin-film transistors is bonded to a self-assembly substrate with which a plurality of light-emitting elements are assembled in an aligned manner, thereby improving a speed and precision of a process of transferring the light-emitting element.

Technical benefits according to the present disclosure are not limited to the above-mentioned benefits. Other benefits and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

A first aspect of the present disclosure provides a display device comprising: a first substrate including a thin-film transistor; a second substrate including a light-emitting element; and a bonding pad disposed between the first substrate and the second substrate, wherein the bonding pad bonds the first substrate and the second substrate to each other and electrically connects the thin-film transistor of the first substrate and the light-emitting element of the second substrate to each other.

In one implementation of the first aspect, the first substrate further includes a plurality of reflective electrode patterns overlapping the bonding pad.

In one implementation of the first aspect, the display device further comprises a plurality of wiring electrodes electrically connected to the light-emitting element and bonded to the bonding pad.

In one implementation of the first aspect, the second substrate further includes: a self-assembly substrate; a black bank disposed on the self-assembly substrate so as to define a display area; a planarization layer disposed on the black bank and having an assembly groove defined therein, wherein the light-emitting element is disposed in the assembly groove; and a pair of assembly electrodes disposed between the black bank and the planarization layer, wherein the pair of assembly electrodes are respectively disposed on both opposing sides of the assembly groove positioned therebetween.

In one implementation of the first aspect, the black bank receives therein a condensing lens pattern having a groove shape having a convex surface toward the self-assembly substrate, wherein a transparent sealant is disposed between the black bank and the assembly electrodes, wherein the transparent sealant fills the condensing lens pattern.

In one implementation of the first aspect, the light-emitting element includes: a nitride semiconductor structure including a first semiconductor layer, an active layer, and a second semiconductor layer; a first electrode; and a second electrode, wherein the nitride semiconductor structure has a trench defined therein extending through the second semiconductor layer and the active layer so as to expose a portion of a surface of the first semiconductor layer at one side of the nitride semiconductor structure, wherein the first electrode fills the trench and is in contact with the first semiconductor layer, wherein the second electrode is in contact with the second semiconductor layer.

In one implementation of the first aspect, the bonding pad includes silver paste or an anisotropic conductive film containing a plurality of conductive particles therein, wherein in a plan view of the display device, the bonding pad has an area larger than an area of the first electrode or the second electrode.

A second aspect of the present disclosure provides a display device comprising: a first substrate including: a base substrate; a thin-film transistor disposed on the base substrate; a first planarization layer disposed on the thin-film transistor; a first reflective electrode pattern disposed on the first planarization layer; and a second reflective electrode pattern spaced apart from the first reflective electrode pattern; a second substrate including: a self-assembly substrate having an assembly groove defined therein; a lower wiring electrode disposed on the assembly groove; a light-emitting element disposed in the assembly groove and having one side contacting the lower wiring electrode; a protective layer covering the light-emitting element and not covering a portion of a surface of the lower wiring electrode so as to be exposed; a second wiring electrode including an upper wiring electrode disposed on the protective layer and in contact with the lower wiring electrode; and a first wiring electrode contacting the other side of the light-emitting element; and a pair of bonding pads respectively overlapping the first and second reflective electrode patterns of the first substrate, wherein one of the bonding pads electrically connects the second reflective electrode pattern and the first wiring electrode to each other, wherein another of the bonding pads electrically connects the first reflective electrode pattern and the second wiring electrode to each other, wherein the bonding pads bond the first and second substrates to each other.

In one implementation of the second aspect, the light-emitting element includes: a nitride semiconductor structure including a first semiconductor layer, an active layer, and a second semiconductor layer; a first electrode; and a second electrode, wherein the nitride semiconductor structure has a vertical structure in which the first semiconductor layer, the active layer, and the second semiconductor layer are arranged vertically and sequentially, wherein the first electrode is disposed on a rear surface of the first semiconductor layer and is in contact with the first wiring electrode, wherein the second electrode is disposed on the second semiconductor layer and is in contact with the lower wiring electrode.

In one implementation of the second aspect, each of the bonding pads includes silver paste or an anisotropic conductive film containing a plurality of conductive particles therein, wherein in a plan view of the display device, each of the bonding pads has an area larger than an area of the first electrode or the second electrode.

A third aspect of the present disclosure provides a method for manufacturing a display device, the method comprising: providing a first substrate including: a base substrate; a thin-film transistor disposed on the base substrate; a first planarization layer disposed on the thin-film transistor; a first reflective electrode pattern disposed on the first planarization layer; a second reflective electrode pattern spaced apart from the first reflective electrode pattern; and bonding pads respectively overlapping the first and second reflective electrode patterns; providing a second substrate including: a self-assembly substrate; a black bank disposed on the self-assembly substrate so as to define a display area; a planarization layer disposed on the black bank and having an assembly groove defined therein; and a pair of assembly electrodes disposed between the black bank and the planarization layer and respectively disposed on both opposing sides of the assembly groove disposed therebetween; aligning a light-emitting element having an electrode with the assembly groove of the second substrate so as to be received in the assembly groove; forming a protective layer on the self-assembly substrate including the light-emitting element so as to have an opening defined therein exposing a portion of a surface of the electrode of the light-emitting element; forming a wiring electrode on the protective layer so as to be in contact with the electrode; and arranging the second substrate including the wiring electrode and the first substrate vertically, and bonding the first substrate and the second substrate to each other via the bonding pads disposed therebetween.

In one implementation of the third aspect, one surface of each of the bonding pads is in contact with a corresponding one of the first and second reflective electrode patterns, while the other surface opposing the one surface of each of the bonding pads is in contact with the wiring electrode.

In one implementation of the third aspect, aligning the light-emitting element having the electrode with the assembly groove of the second substrate so as to be received in the assembly groove includes: inputting the self-assembly substrate into a fluid in which a plurality of light-emitting elements are dispersed; applying a voltage to the pair of assembly electrodes to generate an electric field around the pair of assembly electrodes; and moving one light-emitting element among the plurality of light-emitting elements toward the assembly groove under the electric field.

A fourth aspect of the present disclosure provides a tiling display device comprising a plurality of display units, each of which comprising the above display device.

According to one embodiment of the present disclosure, the display device in which the self-assembly substrate with which the plurality of light-emitting elements are assembled in the aligned manner and the substrate including the thin-film transistor are bonded to each other may be introduced, thereby implementing a large-area display device.

Furthermore, the self-assembly substrate with which the plurality of light-emitting elements are assembled in the aligned manner and the substrate including the thin-film transistor are bonded to each other, thereby preventing misalignment due to tolerance accumulation that occurs during the plurality of transfer processes, and thus implementing a display device with high precision.

Accordingly, there is an advantage in being able to implement a display device including an ultra-small light-emitting element that requires high positional accuracy.

Furthermore, the self-assembly substrate with which the plurality of light-emitting elements are assembled in the aligned manner is first provided, and then, is bonded to the substrate including the thin-film transistor. Thus, the number of the transfer processes may be reduced, thereby implementing process optimization.

Furthermore, the self-assembly substrate with which the plurality of light-emitting elements are assembled in the aligned manner is first provided, and then, is bonded to the substrate including the thin-film transistor. Thus, the plurality of transfer processes using the stamp to transfer the light-emitting element may be omitted, thereby realizing process optimization, and thus, reducing production energy.

Furthermore, the plurality of transfer processes using the stamp may be omitted, thereby preventing decrease in the yield due to the tolerance accumulation occurring during the plurality of transfer processes.

Effects of the present disclosure are not limited to the effects mentioned above, and other effects not mentioned will be clearly understood by those skilled in the art from the descriptions below.

### BRIEF DESCRIPTION OF THE SEVERAL VIEWS OF THE DRAWINGS

FIG. 1 is a plan view schematically showing a display device according to an embodiment of the present disclosure.

FIG. 2 is a cross-sectional view as taken along 2-2 of the display device in FIG. 1.

FIG. 3A and FIG. 3B are cross-sectional views showing a light-emitting element according to an embodiment of the present disclosure.

FIG. 4 is a plan view schematically showing a first substrate of a display device according to an embodiment of the present disclosure.

FIG. 5 is a plan view schematically showing a display device according to another embodiment of the present disclosure.

FIG. 6 is a cross-sectional view as taken along 6-6 of the display device in FIG. 5.

FIG. 7 is a cross-sectional view showing a light-emitting element according to another embodiment of the present disclosure.

FIG. 8 is a cross-sectional view showing a display device according to still another embodiment of the present disclosure.

FIGS. 9A to 9G are diagrams for illustrating a method for manufacturing a display device according to an embodiment of the present disclosure.

FIGS. 10 to 13 are diagrams for illustrating a bonding structure of a display device according to an embodiment of the present disclosure.

### DETAILED DESCRIPTION

Advantages and features of the present disclosure, and a method of achieving the advantages and features will become apparent with reference to embodiments described later in detail together with the accompanying drawings. However, the present disclosure is not limited to the embodiments as disclosed under, but may be implemented in various different forms.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise,” “comprising,” “include,” and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

In addition, it will also be understood that when a first element or layer is referred to as being present “on” a second element or layer, the first element or layer may be disposed directly on the second element or layer or may be disposed indirectly on the second element or layer with a third element or layer being disposed between the first and second elements or layers.

It will be understood that when an element or layer is referred to as being “connected to.” or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after,” “subsequent to,” “before,” etc., another event may occur therebetween unless “directly after,” “directly subsequent” or “directly before” is indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first,” “second,” “third,” and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range even if there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects,” and the like should not be construed such that any aspect or design as described is superior to or advantageous over other aspects or designs.

Further, the term ‘or’ means ‘inclusive or’ rather than ‘exclusive or.’ That is, unless otherwise stated or clear from the context, the expression that ‘x uses a or b’ means any one of natural inclusive permutations.

The terms used in the description below have been selected as being general and universal in the related technical field. However, there may be other terms than the terms depending on the development and/or change of technology, convention, preference of technicians, etc. Therefore, the terms used in the description below should not be understood as limiting technical ideas, but should be understood as examples of the terms for illustrating embodiments.

Further, in a specific case, a term may be arbitrarily selected by the applicant, and in this case, the detailed meaning thereof will be described in a corresponding description section. Therefore, the terms used in the description below should be understood based on not simply the name of the terms, but the meaning of the terms and the contents throughout the Detailed Descriptions.

Hereinafter, a display device according to each embodiment of the present disclosure will be described with reference to the accompanying drawings.

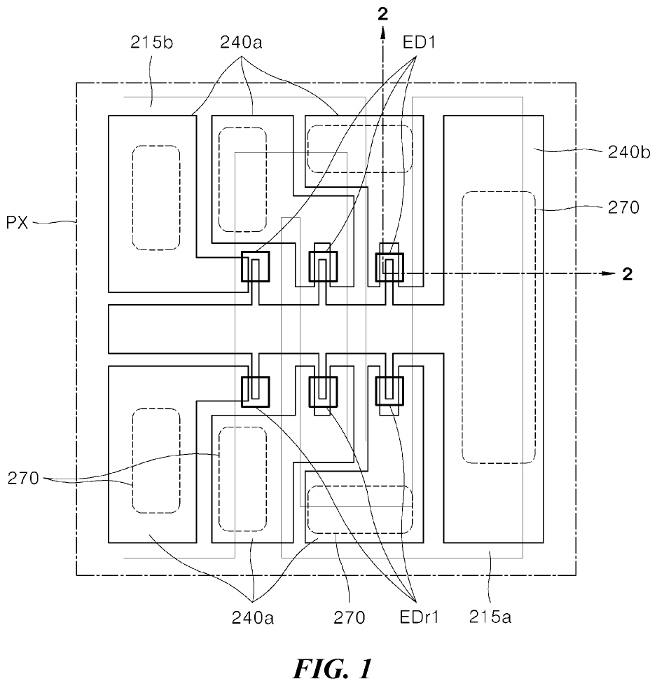

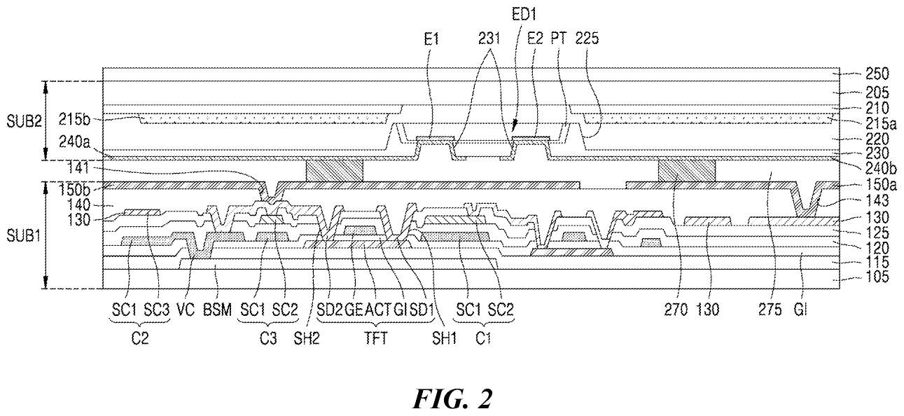

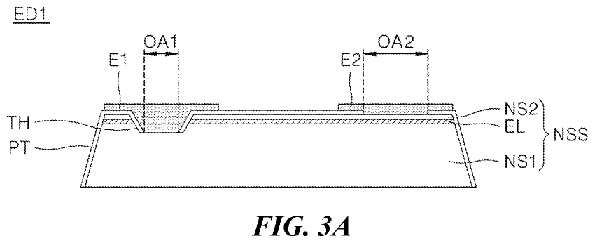

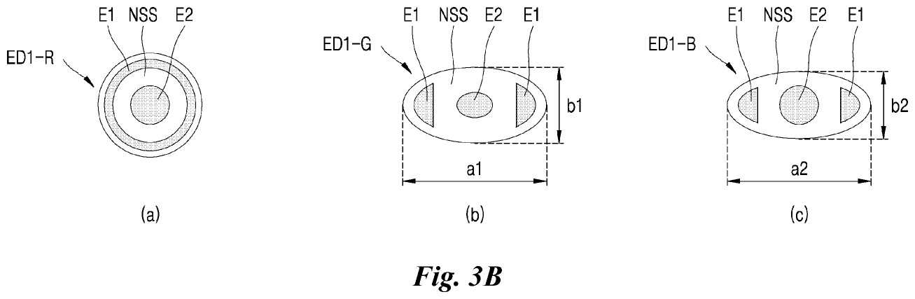

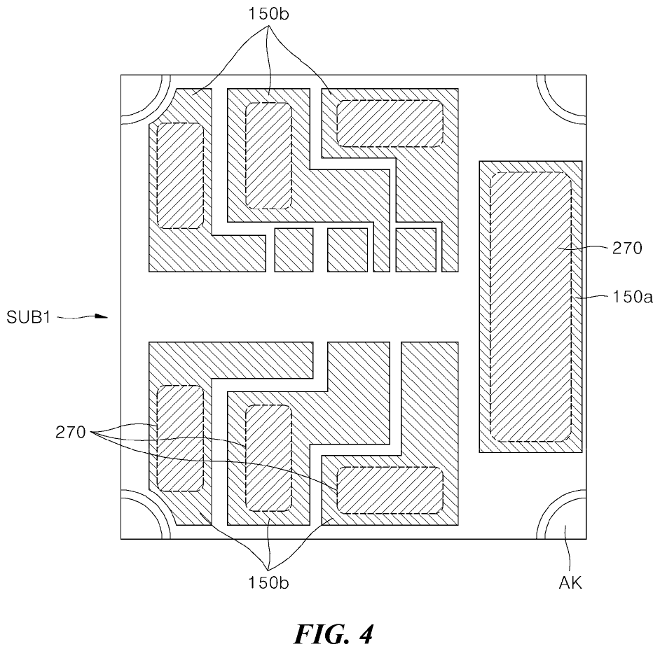

FIG. 1 is a plan view schematically showing a display device according to an embodiment of the present disclosure. FIG. 2 is a cross-sectional view as taken along 2-2 of the display device in FIG. 1. FIG. 3A and FIG. 3B are cross-sectional views showing a light-emitting element according to an embodiment of the present disclosure. FIG. 4 is a plan view schematically showing a first substrate of a display device according to an embodiment of the present disclosure.

Referring to FIGS. 1 to 4, a display device according to an embodiment of the present disclosure may include a plurality of pixels. FIG. 1 shows one pixel PX among the plurality of pixels disposed in the display device. Furthermore, for convenience of illustration, FIG. 1 shows only light-emitting elements ED1 and EDr1, assembly electrodes 215a and 215b, wiring electrodes 240a and 240b, and a bonding pad 270 among components of the display device.

Each of the plurality of pixels may include a plurality of sub-pixels. Each sub-pixel may include a light-emitting area and a circuit area for driving the light-emitting area. The light-emitting area may include the first light-emitting element ED1. The first light-emitting element ED1 may include at least one first light-emitting element ED1 disposed in each of the plurality of sub-pixels. For example, the first light-emitting element ED1 may include a first red light-emitting element, a first green light-emitting element, or a first blue light-emitting element that emits red (R), green (G), or blue (B) light, respectively. However, the present disclosure is not limited thereto.

Furthermore, each of the plurality of sub-pixels may further include a plurality of first redundant light-emitting elements EDr1 for a repair process. For example, the first redundant light-emitting element EDr1 may include a first redundant red light-emitting element, a first redundant green light-emitting element, or a first redundant blue light-emitting element corresponding to and emitting light of the same color as that of the first red light-emitting element, the first green light-emitting element, or the first blue light-emitting element, respectively. Each first light-emitting element ED1 and each first redundant light-emitting element EDr1 may be electrically connected to each other via the wiring electrodes 240a and 240b. This will be described with reference to FIG. 2 below.

In FIG. 2, for convenience of illustration, only one sub-pixel among the plurality of sub-pixels is shown.

Referring to FIG. 1 and FIG. 2, the display device according to an embodiment of the present disclosure may include a first substrate SUB1 including a thin-film transistor TFT and a second substrate SUB2 including the first light-emitting element ED1, wherein the first substrate and the second substrate may be bonded to each other via a bonding pad 270 and may be electrically connected to each other.

The thin-film transistor TFT is disposed on a base substrate 105 of the first substrate SUB1. The thin-film transistor TFT may include a semiconductor layer ACT, a gate electrode GE, and a gate insulating layer GI disposed between the semiconductor layer ACT and the gate electrode GE. A light-shielding layer BSM may be disposed on the base substrate 105. The light-shielding layer BSM may reduce leakage current by preventing light from a position under a bottom of the base substrate 105 from being incident to the semiconductor layer ACT of the thin-film transistor TFT. For example, when light is irradiated to the semiconductor layer ACT, leakage current may occur, thereby deteriorating the reliability of the thin-film transistor TFT. Therefore, the reliability of the thin-film transistor TFT may be improved by disposing the light-shielding layer BSM on the base substrate 105. The light-shielding layer BSM may include an opaque conductive material. A buffer layer 115 including an insulating material may be disposed between the base substrate 105 and the light-shielding layer BSM.

The gate electrode GE and a plurality of first capacitor electrodes SC1 may be disposed on the gate insulating layer GI and may be coplanar with each other. A first interlayer insulating film 120 may be disposed on the gate electrode GE. A plurality of second capacitor electrodes SC2 may be disposed on the first interlayer insulating film 120. The plurality of the second capacitor electrodes SC2 may be respectively disposed to overlap with the plurality of the first capacitor electrodes SC1 while the first interlayer insulating film 120 as a dielectric layer is interposed therebetween, thereby forming a plurality of storage capacitors C1 and C3.

A second interlayer insulating film 125 may be disposed on the first interlayer insulating film 120. A plurality of signal lines 130 may be disposed on the second interlayer insulating film 125. The signal line 130 may be, for example, a data line, a first driving power line, and a second driving power line. Furthermore, a third capacitor electrode SC3 may be disposed on the second interlayer insulating film 125. The third capacitor electrode SC3 may overlap the first capacitor electrode SC1 while the first interlayer insulating film 120 and the second interlayer insulating film 125 acting as a dielectric layer are interposed therebetween, thereby forming another storage capacitor C2.

Source/drain electrodes SD1 and SD2 may be respectively disposed to fill source/drain contact holes SH1 and SH2 extending through the first interlayer insulating film 120, the second interlayer insulating film 125, and the gate insulating layer GI. The source/drain electrodes SD1 and SD2 may be respectively disposed on both opposing sides of the gate electrode GE while the gate electrode GE is interposed therebetween. One source/drain electrode SD2 among the source/drain electrodes SD1 and SD2 may be connected to the light-shielding layer BSM whose a surface is partially exposed via a via contact VC that extends through the gate insulating layer GI and the buffer layer 115.

A first planarization layer 140 may be disposed to cover the plurality of signal lines 130 and the source/drain electrodes SD1 and SD2. Contact holes 141 and 143 may extend through the first planarization layer 140 so as to expose a portion of the surface of the signal line 130 and a portion of the surface of each of the source/drain electrodes SD1 and SD2, respectively.

The contact holes 141 and 143 may include the first contact hole 141 and the second contact hole 143 spaced apart from the first contact hole 141. The first contact hole 141 may expose a portion of the surface of the source/drain electrode SD2, and the second contact hole 143 may expose a portion of the surface of each of some signal lines 130 among the plurality of signal lines 130. A plurality of reflective electrode patterns 150a and 150b may be disposed on the exposed surfaces of the first and second contact holes 141 and 143 and the first planarization layer 140. The plurality of reflective electrode patterns 150a and 150b may reflect light emitted toward the base substrate 105 among the light beams emitted from the light-emitting element toward the light emitting area. The plurality of reflective electrode patterns 150a and 150b may include a metal material with high reflectivity. For example, the plurality of reflective electrode patterns 150a and 150b may include aluminum (Al) or silver (Ag).

The plurality of reflective electrode patterns 150a and 150b may include the first reflective electrode pattern 150a and the second reflective electrode pattern 150b. For example, the first reflective electrode pattern 150a may be connected to the signal line 130 via the second contact hole 143. The second reflective electrode pattern 150b may be connected to the source/drain electrode SD2 via the first contact hole 141. Referring to FIG. 4, a plurality of alignment keys AK may be disposed on the first substrate SUB1 for alignment when bonding with the second substrate SUB2.

The second substrate SUB2 including first light-emitting element ED1 may be disposed so as to face and spaced apart from the plurality of reflective electrode patterns 150a and 150b included in the first substrate SUB1.

A black bank 210 may be disposed on a self-assembly substrate 205 of the second substrate SUB2. The self-assembly substrate 205 may include, for example, glass or a transparent plastic material. The self-assembly substrate 205 may be made of the same material as that of the base substrate 105 of the first substrate SUB1 and thus may be easily modified and managed.

The black bank 210 may have black ink with a thickness of 2 μm to 3 μm. As long as the black bank 210 is made of a material that may block light, the black bank 210 may be disposed on the self-assembly substrate 205. The black bank 210 serves to define a display area where light emitted from the first light-emitting element ED1 is emitted to the outside. Additionally, the black bank 210 may serve as a partition that prevents colors of light beams from adjacent sub-pixels from being mixed with each other.

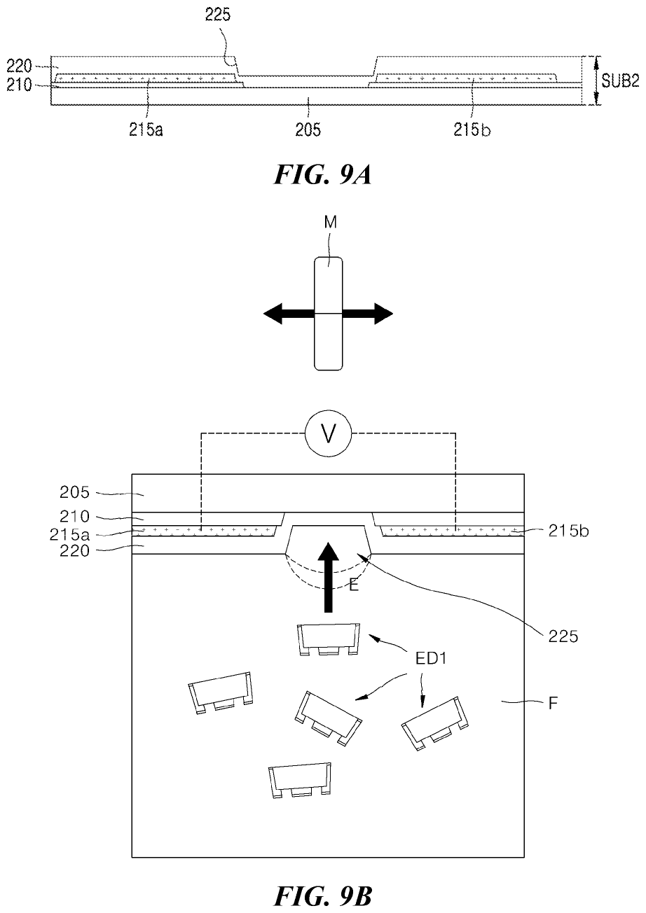

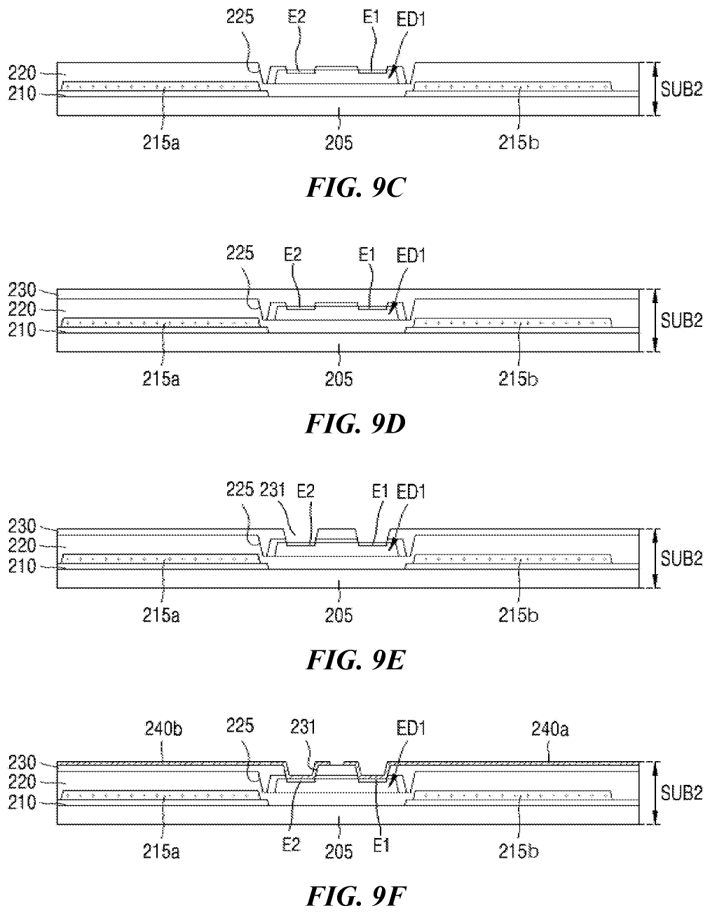

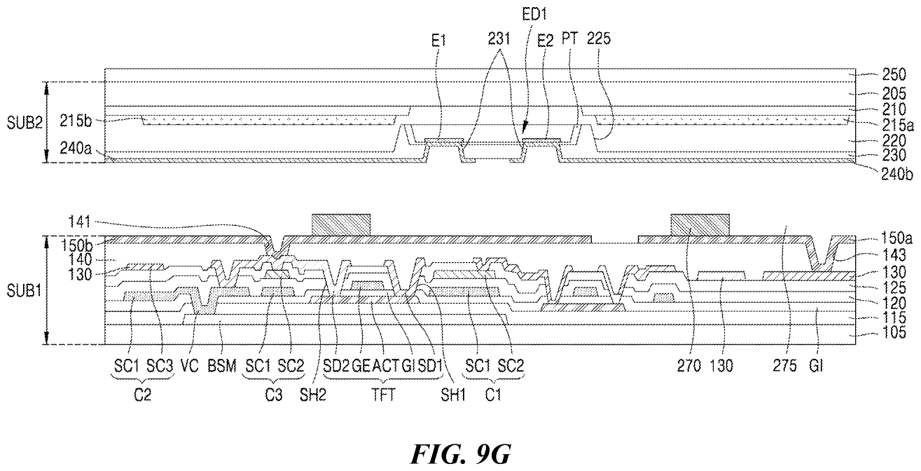

Assembly electrodes 215a and 215b may be disposed on the black bank 210. The assembly electrodes 215a and 215b may include the first assembly electrode 215a and the second assembly electrode 215b. The first assembly electrode 215a and the second assembly electrode 215b may be arranged to be spaced apart from each other. In the self-assembly process, a voltage is applied to the first assembly electrode 215a and the second assembly electrode 215b to generate an electric field to attract the first light-emitting element ED1 to the assembly groove. This will be described later with reference to FIG. 9A to FIG. 9G.

The assembly electrodes 215a and 215b may be made of a transparent electrode including a transparent metal oxide such as indium-tin-oxide (ITO) or indium-zinc-oxide (IZO). Additionally, the assembly electrodes 215a and 215b may include a transparent metal material capable of generating an electric field.

A second planarization layer 220 may be disposed on the first assembly electrode 215a and the second assembly electrode 215b. The second planarization layer 220 may include an assembly groove 225. The assembly groove 225 may be disposed in a position corresponding to an area where the first light-emitting element ED1 is disposed. The second planarization layer 220 may extend to cover the first and second assembly electrodes 215a and 215b. The second planarization layer 220 may include a photo active compound (PAC) material.

The first light-emitting element ED1 may be disposed in the assembly groove 225. The first light-emitting element ED1 according to an embodiment of the present disclosure may have a flip chip shape as shown in FIG. 3A.

Referring to FIG. 3A and FIG. 3B, the first light-emitting element ED1 according to an embodiment of the present disclosure may include a nitride semiconductor structure NSS, a passivation pattern PT, a first electrode E1, and a second electrode E2. The first light-emitting element ED1 may be embodied as a micro-LED. The nitride semiconductor structure NSS may include a first semiconductor layer NS1, an active layer EL, and a second semiconductor layer NS2. The nitride semiconductor structure NSS may have a trench TH that extends through the second semiconductor layer NS2 and the active layer EL so as to partially expose a surface of the first semiconductor layer NS1 at one side of the nitride semiconductor structure NSS.

The first electrode E1 may fill the trench TH, and may contact the first semiconductor layer NS1, and may be coplanar with the second electrode E2.

The passivation pattern PT may cover a portion of an outer surface of the nitride semiconductor structure NSS and a sidewall of the trench TH. The passivation pattern PT may have a first open area OA1 exposing a portion of a surface of the first semiconductor layer NS1 and a second open area OA2 exposing a portion of a surface of the second semiconductor layer NS2. The first electrode E1 may be in contact with the first semiconductor layer NS1 exposed through the first open area OA1. The second electrode E2 may be in contact with the second semiconductor layer NS2 exposed through the second open area OA2. The first electrode E1 and the second electrode E2 may be spaced apart from each other and may be insulated from each other via the passivation pattern PT.

The first semiconductor layer NS1 is a layer for supplying electrons to the active layer EL, and may include a nitride-based semiconductor containing a first conductivity type impurity. For example, the first conductivity type impurity may include N-type impurity. The active layer EL is a layer for emitting light and may include a multi quantum well (MQW) structure having a well layer and a barrier layer with a higher band gap than that of the well layer.

The second semiconductor layer NS2 is a layer for injecting holes into the active layer EL. The second semiconductor layer NS2 may include a nitride-based semiconductor containing a second conductivity type impurity. For example, the second conductivity type impurity may include P-type impurity. The active layer EL may emit light based on a combination of electrons and holes supplied from the first semiconductor layer NS1 and the second semiconductor layer NS2, respectively.

The first light-emitting element ED1 may be covered with a protective layer 230. The protective layer 230 serves to planarize the steps caused by the assembly groove 225 and the first light-emitting element ED1. The protective layer 230 may be disposed to fill the assembly groove 225 and extend to the second planarization layer 220.

The protective layer 230 may include an opening 231 that exposes a portion of the surface of each of the first electrode E1 and the second electrode E2 of the first light-emitting element ED1. A portion of each of the first wiring electrode 240a and the second wiring electrode 240b may be disposed on the exposed surface of the opening 231. The first wiring electrode 240a and the second wiring electrode 240b may be in contact with the first electrode E1 and the second electrode E2 exposed through the opening 231, respectively. For example, the first wiring electrode 240a may be in contact with the first electrode E1 of the first light-emitting element ED1, and the second wiring electrode 240b may be in contact with the second electrode E2 of the first light-emitting element ED1.

This first light-emitting element ED1 may implement each of a first red light-emitting element that emits red (R) light, a first green light-emitting element that emits green (G) light, and a first blue light-emitting element that emits blue (B) light so as to have different shapes.

For example, referring to FIG. 3B, the first red light-emitting element ED1-R may have the shape of a concentric circle. The first red light-emitting element ED1-R may include the first electrode E1 surrounding the second electrode E2 disposed at a center. The first green light-emitting element ED1-G may have an oval shape with a first major axis a1 and a first minor axis b1. The first green light-emitting element ED1-G may include the first electrodes E1 respectively disposed on both opposing sides of the second electrode E2 disposed therebetween. The first blue light-emitting element ED1-B may have an oval shape with a second major axis a2 and a second minor axis b2. The first blue light-emitting element ED1-B may include the first electrodes E1 respectively disposed on both opposing sides of the second electrode E2 disposed therebetween.

The length of the second major axis a2 of the first blue light-emitting element ED1-B may be relatively larger than the length of the first major axis a1 of the first green light-emitting element ED1-G. The length of the first minor axis b1 of the first green light-emitting element ED1-G may be relatively larger than the length of the second minor axis b2 of the first blue light-emitting element ED1-B.

The first substrate SUB1 including the thin-film transistor TFT and the second substrate SUB2 including the first light-emitting element ED1 may be bonded to each other via the bonding pad 270 and may be electrically connected to each other via the bonding pad 270.

Referring to FIGS. 1 to 4, the bonding pad 270 may be disposed to overlap each of the reflective electrode patterns 150a and 150b. The bonding pad 270 may include a conductive material. For example, the bonding pad 270 may include silver paste (Ag paste) or an anisotropic conductive film (ACF) containing a plurality of conductive particles.

The bonding pad 270 may have an area that is larger than an area of the first electrode E1 or the second electrode E2 of the first light-emitting element ED1 in a plane view. Since the area of the bonding pad 270 is larger than that of each of the electrodes E1 and E2 of the first light-emitting element ED1 in the plane view, the first substrate SUB1 and the second substrate SUB2 may be easily connected electrically to each other via the bonding pad 270 even when the bonding pad 270 is interposed therebetween.

The first electrode E1 of the first light-emitting element ED1 may be electrically connected to the first reflective electrode pattern 150a and the source/drain electrode SD2 via the bonding pad 270 in contact with the first wiring electrode 240a. The second electrode E2 of the first light-emitting element ED1 may be electrically connected to the second reflective electrode pattern 150b and the signal line 130 via the bonding pad 270 in contact with the second wiring electrode 240b. The first electrode E1 and the second electrode E2 may be made of the same material, including a transparent metal oxide such as indium-tin-oxide (ITO) or indium-zinc-oxide (IZO).

A space between the first substrate SUB1 and the second substrate SUB2 may be filled with a filler 275 made of a transparent material. The second substrate SUB2 may further include a cover layer 250 disposed on the second substrate SUB2. The cover layer 250 may further include a functional optical film such as an anti-shatter film. The cover layer 250 may be attached to the second substrate SUB2 via an optically clear adhesive (OCA). However, the present disclosure is not limited thereto.

In one example, the light-emitting element may be embodied as a vertical micro-LED. This will be described with reference to the drawings.

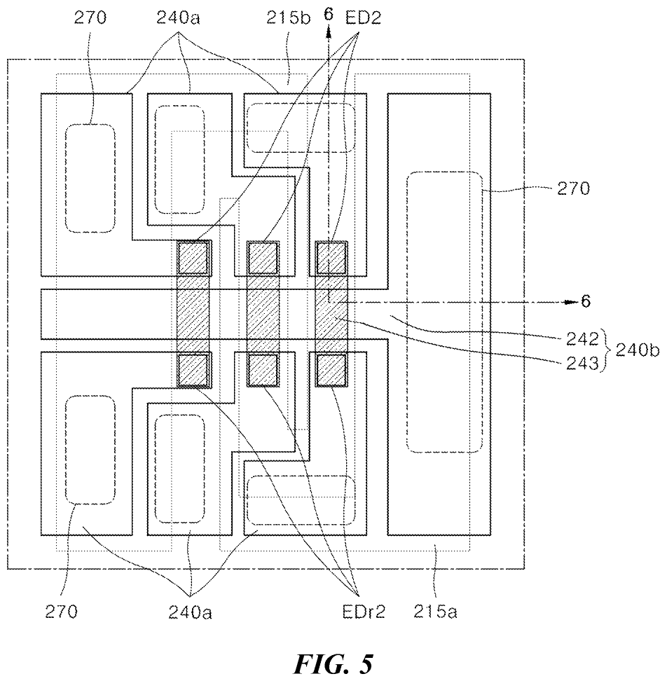

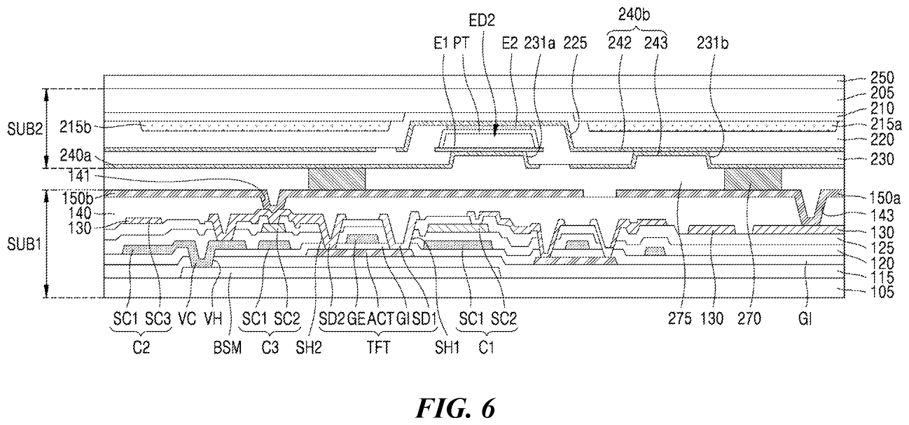

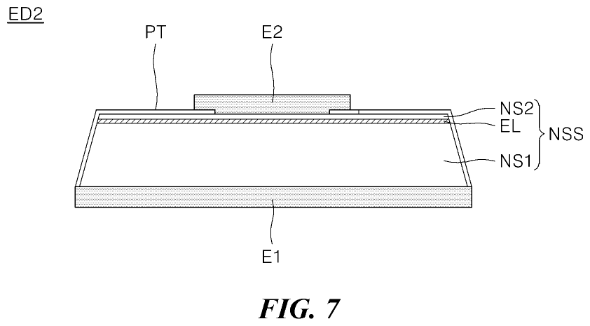

FIG. 5 is a plan view schematically showing a display device according to another embodiment of the present disclosure. FIG. 6 is a cross-sectional view as taken along 6-6 of the display device in FIG. 5. FIG. 7 is a cross-sectional view showing a light-emitting element according to another embodiment of the present disclosure. In this regard, the components of the first substrate are the same as those in FIG. 2. Accordingly, the components indicated with the same reference numerals as those in FIG. 2 may be briefly described or descriptions thereof may be omitted.

Referring to FIGS. 5 to 7, a display device according to an embodiment of the present disclosure may include a plurality of pixels. FIG. 5 shows one pixel among the plurality of pixels disposed in the display device. In FIG. 5, for convenience of illustration, only light-emitting elements ED2 and EDr2, the assembly electrodes 215a and 215b, the wiring electrodes 240a and 240b, and the bonding pad 270 among the components of the display device are shown. In FIG. 6, for convenience of illustration, only one sub-pixel among the plurality of sub-pixels is shown.

A display device according to another embodiment of the present disclosure may include the first substrate SUB1 including the thin-film transistor TFT and the second substrate SUB2 including the second light-emitting element ED2, wherein the first substrate SUB1 and the second substrate SUB2 may be bonded to each other via the bonding pad 270 and may be electrically connected to each other via the bonding pad 270.

The thin-film transistor TFT including the semiconductor layer ACT, the gate electrode GE, and the gate insulating layer GI may be disposed in the first substrate SUB1. The first planarization layer 140 covering the thin-film transistor TFT and the circuit wiring may be disposed on the base substrate 105 of the first substrate SUB1. The plurality of reflective electrode patterns 150a and 150b may be disposed on the first planarization layer 140.

The second substrate SUB2 having the second light-emitting element ED2 may be disposed so as to face and may be spaced apart from the plurality of reflective electrode patterns 150a and 150b disposed in the first substrate SUB1. The black bank 210, the plurality of assembly electrodes 215a and 215b, and the second planarization layer 220 may be disposed on the self-assembly substrate 205 of the second substrate SUB2.

The second planarization layer 220 may include the assembly groove 225. The assembly groove 225 may be disposed in a position corresponding to an area where the second light-emitting element ED2 is disposed. The second planarization layer 220 may extend to cover the first and second assembly electrodes 215a and 215b.

A lower wiring electrode 242 may be disposed on the assembly groove 225. The lower wiring electrode 242 may be disposed on the exposed surface of the assembly groove 225 and may extend to the upper surface of the second planarization layer 220.

The second light-emitting element ED2 may be disposed on the lower wiring electrode 242. The second light-emitting element ED2 may include at least one second light-emitting element ED2 disposed in each of the plurality of sub-pixels. For example, the second light-emitting element ED2 may include a second red light-emitting element, a second green light-emitting element, or a second blue light-emitting element that emits red (R), green (G), or blue (B) light, respectively. However, the present disclosure is not limited thereto. Furthermore, each of the plurality of sub-pixels may further include a second redundant light-emitting element EDr2 for a repair process. For example, the second redundant light-emitting element EDr2 may include a second redundant red light-emitting element, a second redundant green light-emitting element, or a second redundant blue light-emitting element corresponding to and emitting light of the same color as that of the second red light-emitting element, the second green light-emitting element, or the second blue light-emitting element, respectively.

Referring to FIG. 6, the second light-emitting element ED2 according to another embodiment of the present disclosure may include the nitride semiconductor structure NSS, the passivation pattern PT, the first electrode E1, and the second electrode E2. The second light-emitting element ED2 may be embodied as a micro-LED. The nitride semiconductor structure NSS may have a vertical type structure in which the first semiconductor layer NS1, the active layer EL, and the second semiconductor layer NS2 are arranged vertically in this order.

The passivation pattern PT may cover a portion of the outer surface of the nitride semiconductor structure NSS and may not cover one surface of the first semiconductor layer NS1 and a portion of a surface of the second semiconductor layer NS2 so as to be exposed. The first electrode E1 may be in contact with the exposed one surface of the first semiconductor layer NS1 not covered with the passivation pattern PT, and the second electrode E2 may be in contact with the exposed portion of the surface of the second semiconductor layer NS2 not covered with the passivation pattern PT.

The second light-emitting element ED2 and the lower wiring electrode 242 may be covered with the protective layer 230. The protective layer 230 serves to planarize the steps caused by the assembly groove 225 and the second light-emitting element ED2.

The protective layer 230 may include a first opening hole 231a exposing a portion of the surface of the first electrode E1 of the second light-emitting element ED2 and a second opening hole 231b exposing a portion of the surface of the lower wiring electrode 242.

An upper wiring electrode 243 and the first wiring electrode 240a may be disposed on an exposed surface of each of the first and second opening holes 231a and 231b. The upper wiring electrode 243 may contact the lower wiring electrode 242 exposed through the second opening hole 231b to constitute the second wiring electrode 240b.

The first substrate SUB1 including the thin-film transistor TFT and the second substrate SUB2 including the second light-emitting element ED2 may be bonded to each other via the bonding pad 270 and may be electrically connected to each other via the bonding pad 270. The bonding pad 270 may include a conductive material. The bonding pad 270 may have an area larger than that of the first electrode E1 or the second electrode E2 of the second light-emitting element ED2 in a plane view.

The first electrode E1 of the second light-emitting element ED2 may be electrically connected to the first reflective electrode pattern 150a and the source/drain electrode SD2 via the bonding pad 270 in contact with the first wiring electrode 240a. The second electrode E2 of the second light-emitting element ED2 may be electrically connected to the second reflective electrode pattern 150b and the signal line 130 via the bonding pad 270 in contact with the second wiring electrode 240b including the lower wiring electrode 242 and the upper wiring electrode 243.

The space between the first substrate SUB1 and the second substrate SUB2 may be filled with the filler 275 made of a transparent material. The second substrate SUB2 may further include the cover layer 250 disposed on the second substrate SUB2.

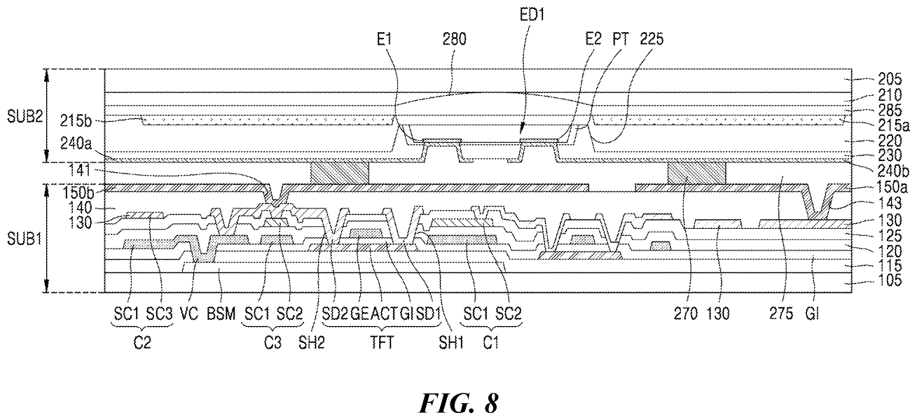

In one example, light condensing efficiency may be improved by including a light condensing lens pattern disposed on the self-assembly substrate. This will be described with reference to FIG. 8 below.

FIG. 8 is a cross-sectional view showing a display device according to still another embodiment of the present disclosure. In this regard, the components of the first substrate are the same as those in FIG. 2. Accordingly, the components indicated with the same reference numerals as those in FIG. 2 may be briefly described or descriptions thereof may be omitted.

Referring to FIG. 8, the thin-film transistor TFT including the semiconductor layer ACT, the gate electrode GE, and the gate insulating layer GI may be disposed in the first substrate SUB1. The first planarization layer 140 covering the thin-film transistor TFT and the circuit wiring may be disposed on the base substrate 105 of the first substrate SUB1. The plurality of reflective electrode patterns 150a and 150b may be disposed on the first planarization layer 140.

The second substrate SUB2 including the first light-emitting element ED1 may be disposed so as to face and be spaced apart from the reflective electrode patterns 150a and 150b disposed in the first substrate SUB1.

The black bank 210 may be disposed on the self-assembly substrate 205 of the second substrate SUB2. The black bank 210 may receive therein a condensing lens pattern 280 defined therein including a convex surface. The condensing lens pattern 280 may be embodied as a groove having a convex surface convexly protruding toward the self-assembly substrate 205, wherein the convex surface may act as a display surface from which light is emitted. A plurality of condensing lens patterns 280 may be arranged so as to correspond to a plurality of first light-emitting elements ED1 arranged in the display device. A transparent sealant 285 may fill the groove as the condensing lens pattern 280 defined in the black bank 210 while being disposed between the black bank 210 and the assembly electrodes 215a and 215b. Accordingly, the condensing lens pattern 280 may have a shape of a convex lens.

The transparent sealant 285 may include a transparent material so that light emitted from the first light-emitting element ED1 may transmit therethrough out of the self-assembly substrate 205. The other surface of the condensing lens pattern 280 filled with the transparent sealant 285 opposite to one surface thereof as the convex surface may be flat.

The plurality of assembly electrodes 215a and 215b are disposed on the other surface of the transparent sealant 285 non-contacting the black bank 210. The assembly electrodes 215a and 215b may include the first assembly electrode 215a and the second assembly electrode 215b that are spaced apart from each other.

The second planarization layer 220 including the assembly groove 225 may be disposed on the first assembly electrode 215a and the second assembly electrode 215b. The first light-emitting element ED1 may be disposed in the assembly groove 225. The first light-emitting element ED1 may include at least one first light-emitting element ED1 disposed in each of the plurality of sub-pixels. In the embodiment of the present disclosure, a flip chip-shaped light-emitting element is shown for convenience of illustration. However, the present disclosure is not limited thereto. For example, the light-emitting element may have a vertical structure.

The first light-emitting element ED1 may be disposed at a position corresponding to a position of the condensing lens pattern 280 including the convex surface. In an embodiment of the present disclosure, the condensing lens pattern 280 and the black bank 210 may be formed in the same process. Accordingly, the precision of alignment between the condensing lens pattern 280 and the first light-emitting element ED1 may be improved. In addition, a separate process for forming the condensing lens pattern 280 in addition to the process that forms the black bank 210 may not be required. Thus, the manufacturing process may be reduced, thereby reducing accumulation of tolerances due to the increase in the number of steps of the manufacturing process. Accordingly, the precision of alignment may be improved, and the light condensing efficiency may be improved.

In the display device according to the embodiment of the present disclosure, the first substrate SUB1 including the thin-film transistor TFT and the second substrate SUB2 including the first light-emitting element ED1 may be bonded to each other via the bonding pad 270 and may be electrically connected to each other via the bonding pad 270.

In order to manufacture a display device in which both a thin-film transistor and a light-emitting element are disposed on a single panel substrate, a transfer process is performed to transfer a plurality of light-emitting elements onto the panel substrate on which the thin-film transistor has been disposed, and then, an additional process of forming a wiring electrode to drive the light-emitting element should be performed.

However, during the process of forming the wiring electrode, moisture may penetrate into the thin-film transistor or static electricity may be generated, which may cause the electrical characteristics of the thin-film transistor to deteriorate to reduce reliability thereof.

Furthermore, the transfer process of transferring the plurality of light-emitting elements to the panel substrate involves first transferring the light-emitting elements grown on a separate growth substrate onto a transfer stamp, and second transferring the light-emitting elements from the transfer stamp to a panel substrate on which the thin-film transistor has been formed. However, because the transfer process is performed via the transfer stamp, several repetitions are required depending on a size of the stamp, and position tolerances depending on steps accumulate such that accuracy deteriorates.

Specifically, the transfer stamp used in the first transfer process of the light-emitting element may be made of a polymer material, and thus may be deformed during the process of manufacturing and storing the stamp. Accordingly, there is a limit to increasing the area size of the stamp. As there is a limit to increasing the area size of the stamp, the same transfer process should be performed repeatedly multiple times in order to transfer the light-emitting elements to the panel substrate of a desired area size. For example, the process of first-transferring the light-emitting element grown on a separate growth substrate onto the transfer stamp and then second-transferring the light-emitting element from the transfer stamp to the panel substrate on which the thin-film transistor has been formed should be repeated.

A transfer speed of the light-emitting elements decreases as the number of light-emitting elements transferred at one time using the stamp depending on a spacing between the light-emitting elements transferred onto the panel substrate decreases. In a large area-sized display device with relatively low resolution in which the spacing between neighboring light-emitting elements is relatively larger than that in a high-resolution display device, the productivity thereof decreases as the number of second-transferring steps of the light-emitting element to the panel substrate increases.

Furthermore, in each of the first transfer process and the second transfer process, a step of aligning the position of the light-emitting element is performed to prevent an over-transfer defect in which the light-emitting element is transferred to a location other than a target location or to prevent a non-transfer defect that the light-emitting element is not transferred to the target location. In other words, in the first transfer process and the second transfer process, a first position alignment step and a second position alignment step in which positions are aligned with each other using devices such as high-resolution cameras and laser sensors are performed, respectively. However, as a first tolerance occurs in the first position alignment step of the first transfer process, and the second tolerance occurs in the second position alignment step of the second transfer process in a state in which the first tolerance has been present, such that the tolerances accumulate.

Furthermore, as a plurality of position alignment steps are required to manufacture a display device of a large area size, tolerances may accumulate as the number of the position alignment steps increases. As the tolerances accumulate, the positional accuracy of the light-emitting elements may deteriorate. Accordingly, there is a problem in realizing the positional accuracy of the light-emitting element with an ultra-small size such as a micro-LED.

However, in an embodiment of the present disclosure, the self-assembly substrate on which the plurality of light-emitting elements are assembled and aligned with each other may be directly bonded to the substrate on which the thin-film transistor has been disposed, thereby omitting the transfer process of the light-emitting element using the stamp. Accordingly, this may implement the display device with high precision by preventing the positional misalignment due to the tolerance accumulation that occurs during the plurality of transfer process. This makes it possible to implement a display device that includes ultra-small light-emitting elements that require high positional accuracy.

This will be described with reference to the drawings.

FIGS. 9A to 9G are diagrams for illustrating a method for manufacturing a display device according to an embodiment of the present disclosure.

Referring to FIG. 9A, the black bank 210, the assembly electrodes 215a and 215b, and the second planarization layer 220 having the assembly groove 225 defined therein are formed on the self-assembly substrate 205 which may be made of a transparent material such as glass. The black bank 210 may include an opening that exposes a portion of the surface of the self-assembly substrate 205, which acts as the display area that emits light from the light-emitting element to the outside. To this end, a coating layer for the black bank may be formed on an entirety of the surface of the self-assembly substrate 205 and may be patterned to form the black bank 210 having the opening defined therein. Specifically, the coating layer for the black bank may be applied at a thickness of 2 μm to 3 μm, and an area where the opening is to be disposed may be selectively exposed to light, and then a development process may be performed thereon to remove a portion of the coating layer to form the black bank 210 including the opening.

The plurality of assembly electrodes 215a and 215b are formed on the black bank 210. For this purpose, a transparent electrode layer is formed on an entire surface of each of the black bank 210 and the self-assembly substrate 205. Next, the transparent electrode layer is patterned to form the first assembly electrode 215a and the second assembly electrode 215b spaced apart from the first assembly electrode 215a. The plurality of assembly electrodes 215a and 215b may overlap the black bank 210 such that a portion of the surface of the self-assembly substrate 205 is exposed. The transparent electrode layer may include a transparent metal oxide such as indium-tin-oxide (ITO) or indium-zinc-oxide (IZO).

Subsequently, the second planarization layer 220 is formed so as to cover both the first assembly electrode 215a and the second assembly electrode 215b, and then a plurality of assembly grooves 225 are formed in the second planarization layer 220 in a patterning process. For example, the second planarization layer 220 may include a photosensitive compound (PAC) material. In the drawing, one assembly groove 225 is shown for convenience of illustration. However, the plurality of assembly grooves 225 may be defined in the self-assembly substrate 205. For example, the number of the plurality of assembly grooves 225 may be equal to the number of light-emitting elements to be disposed on the self-assembly substrate 205.

Next, in the dielectrophoresis manner, the plurality of light-emitting elements are respectively self-aligned with the plurality of assembly grooves 225 so as to be received in the plurality of assembly grooves 225.

Referring to FIG. 9B, the self-assembly substrate 205 is introduced into a self-assembly chamber filled with a fluid F in which the plurality of first light-emitting elements ED1 are dispersed. The first light-emitting element ED1 may be configured to include a magnetic material. A direction in which the self-assembly substrate 205 is introduced into the self-assembly chamber may be in a direction in which the assembly groove 225 faces and contacts the fluid F. On the self-assembly substrate 205, the pair of assembly electrodes 215a and 215b may be respectively disposed on both opposing sides of the assembly groove 225 disposed therebetween. A voltage V is applied to the assembly electrodes 215a and 215b to generate an electric field E to serve to attract the first light-emitting element ED1 toward the assembly groove 225, as indicated by an arrow.

A magnet M is disposed on top of the other surface opposite to one surface of the self-assembly substrate 205 on which the assembly electrodes 215a and 215b are disposed. The first light-emitting element ED1 among the plurality of light-emitting elements dispersed in the fluid F may be aligned with and received in the assembly groove 225 by performing the translational movement of the magnet M while applying the voltage to the assembly electrodes 215a and 215b. In an embodiment of the present disclosure, the first light-emitting element ED1 of a flip chip shape is shown for convenience of illustration (see for example, FIG. 9C) . However, the first light-emitting element ED1 is not limited thereto. For example, the first light-emitting element ED1 may have a vertical structure.

In an embodiment of the present disclosure, as the process of self-aligning the plurality of light-emitting elements with the plurality of assembly grooves 225 of the self-assembly substrate 205 is carried out in the dielectrophoretic manner, the process of transferring the light-emitting elements to the transfer stamp may be eliminated. Accordingly, the process step of repeatedly transferring the light-emitting element to the transfer stamp may be removed, thereby improving a transfer speed and thus optimizing the process. Furthermore, decrease in the yield occurring when the transfer process is repeated multiple times may be prevented.

Referring to FIG. 9D, the protective layer 230 is formed on the self-assembly substrate 205 including the first light-emitting element ED1 aligned with and disposed in the assembly groove 225. The protective layer 230 may be formed on the second planarization layer 220 so as to fill a remaining portion of an inner space of the assembly groove 225 in which the first light-emitting element ED1 has been received.

Referring to FIG. 9E, the protective layer 230 is patterned to form each of the openings 231 that exposes a portion of the surface of each of the first electrode E1 and the second electrode E2 of the first light-emitting element ED1.

Referring to FIG. 9F, the second substrate SUB2 is prepared by forming each of the wiring electrodes 240a and 240b on each of the exposed surfaces of the openings 231 formed in the protective layer 230. The wiring electrodes 240a and 240b may include the first wiring electrode 240a and the second wiring electrode 240b spaced away from the first wiring electrode 240a. The first wiring electrode 240a and the second wiring electrode 240b may be in contact with the first electrode E1 and the second electrode E2, respectively.

Referring to FIG. 9G, the first substrate SUB1 including the thin-film transistor TFT is provided. The first substrate SUB1 may include the plurality of reflective electrode patterns 150a and 150b and a plurality of bonding pads 270. The second substrate SUB2 including the first light-emitting element ED1 may be placed so as to face and be spaced apart from the plurality of reflective electrode patterns 150a and 150b and the plurality of bonding pads 270 included in the first substrate SUB1. In this regard, the second substrate SUB2 may be oriented so that the first wiring electrode 240a and the second wiring electrode 240b thereof face the plurality of bonding pads 270, respectively.

Subsequently, the method may bond the second substrate SUB2 and the first substrate SUB1 to each other via the bonding pad 270 and may electrically connect the second substrate SUB2 to the first substrate SUB1 including the thin-film transistor TFT via the bonding pad 270. In this way, the display device may be manufactured. In this regard, one surface of each of the pair of the bonding pads 270 may be in contact with a corresponding one of the plurality of reflective electrode patterns 150a and 150b, while the other surface opposite to the one surface thereof may be in contact with a corresponding one of the first wiring electrode 240a and the second wiring electrode 240b.

In the display device according to an embodiment of the present disclosure, the wiring electrode 240a of the second substrate may be electrically connected to the reflective electrode pattern 150b of the first substrate via a first bonding pad 270, while the wiring electrode 240b of the second substrate may be electrically connected to the reflective electrode pattern 150a of the first substrate via a second bonding pad 270. Accordingly, a process in which the plurality of light-emitting elements are transferred to the transfer stamp, and then transferred from the transfer stamp onto the panel substrate including the thin-film transistor, and then a wiring electrode for driving the light-emitting element is formed may be omitted.

That is, in one embodiment of the present disclosure, in a state in which the light-emitting element ED1 or ED2 are assembled with the self-assembly substrate 205 of the second substrate SUB2 in a self-aligned manner, the second substrate SUB2 may be bonded to the first substrate SUB1 via the bonding pad. Thus, the bonding between the substrates and the electrical connection between the electrodes may be made simultaneously without the process of transferring the light-emitting element to the transfer stamp. Therefore, the situation in which during the additional process of forming the wiring electrode for driving the light-emitting element, moisture invades into the thin-film transistor or static electricity is generated, thereby deteriorating the electrical characteristics of the thin-film transistor to reduce reliability thereof may be prevented.

Furthermore, in a state in which the light-emitting element ED1 or ED2 are assembled with the self-assembly substrate 205 of the second substrate SUB2 in a self-aligned manner, the second substrate SUB2 may be bonded to the first substrate SUB1 via the bonding pad. Thus, repeating the plurality of transfer processes using the transfer stamp may be omitted, thereby prevent positional tolerances from accumulating. Accordingly, a decrease in precision may be prevented.

In the display device according to an embodiment of the present disclosure, the first substrate SUB1 and the second substrate SUB2 may be bonded to each other in various manner.

Hereinafter, a bonding manner in which the first substrate SUB1 and the second substrate SUB2 may be bonded to each other in the display device according to an embodiment of the present disclosure will be described with reference to the drawings.

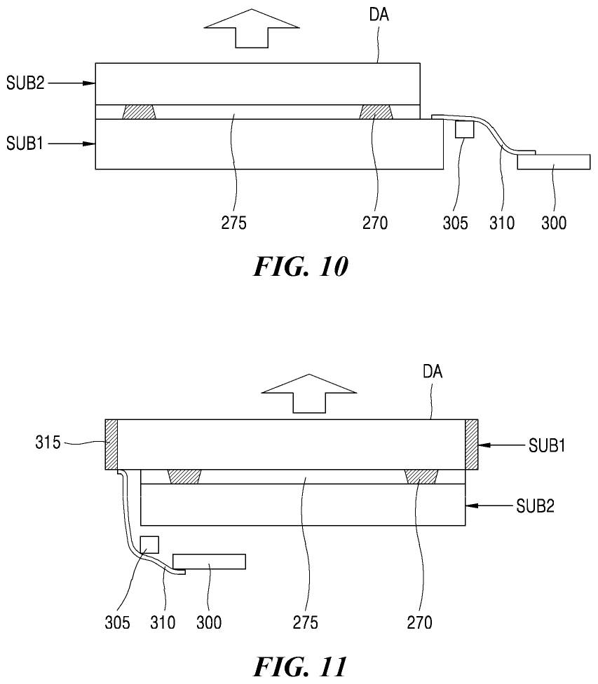

FIGS. 10 to 13 are diagrams for illustrating a bonding manner in which the first substrate SUB1 and the second substrate SUB2 may be bonded to each other in the display device according to embodiments of the present disclosure.

Referring to FIG. 10, in the display device according to an embodiment of the present disclosure, the first substrate SUB1 including the thin-film transistor TFT is disposed at a lower level, while the second substrate SUB2 including the light-emitting element is disposed at an upper level. The bonding pad 270 is disposed therebetween. The first and second substrates are bonded to each other via the bonding pad 270. In this regard, one surface of the second substrate SUB2 may be a display surface DA from which light emitted from the light-emitting element is emitted to the outside.

A driver including a printed circuit board 300 connected to a circuit film 310 on which an integrated circuit chip 305 to transmit various signals to each of the sub-pixels including the thin-film transistor TFT or the light-emitting element is mounted may be disposed at at least one side end of the first substrate SUB1. For example, the signals transmitted to the sub-pixels may include high-potential voltage, low-potential voltage, a scan signal, or a data signal. In one implementation of the present disclosure, a configuration in which the driver including the printed circuit board 300 connected to the circuit film 310 on which the integrated circuit chip 305 is mounted is disposed at one end of the first substrate SUB1 is set forth. However, the present disclosure is not limited thereto.

Referring to FIG. 11, in a display device according to another embodiment of the present disclosure, the first substrate SUB1 including the thin-film transistor TFT is disposed at an upper level, while the second substrate SUB2 including the light-emitting element is disposed at a lower level. The bonding pad 270 is disposed therebetween. The first and second substrates are bonded to each other via the bonding pad 270. In this regard, one surface of the first substrate SUB1 may be a display surface DA from which light emitted from the light-emitting element is emitted to the outside.

The driver including the printed circuit board 300 connected to the circuit film 310 on which the integrated circuit chip 305 to transmit various signals to each of the sub-pixels including the thin-film transistor TFT or the light-emitting element is mounted may be disposed at at least one side end of the first substrate SUB1. For example, the signals transmitted to the sub-pixels may include high-potential voltage, low-potential voltage, a scan signal, or a data signal. In one implementation of the present disclosure, a configuration in which the driver including the printed circuit board 300 connected to the circuit film 310 on which the integrated circuit chip 305 is mounted is disposed at one end of the first substrate SUB1 is set forth. However, the present disclosure is not limited thereto. Furthermore, an outer side surface of the first substrate SUB1 may be covered with a sealing 315. For example, the sealing 315 may surround the outer side surfaces of four edges of the first substrate SUB1.

In one example, the display device according to the embodiment of the present disclosure may be embodied as each of a plurality of display panel units which may be arranged in a matrix manner to implement a tiling display device.

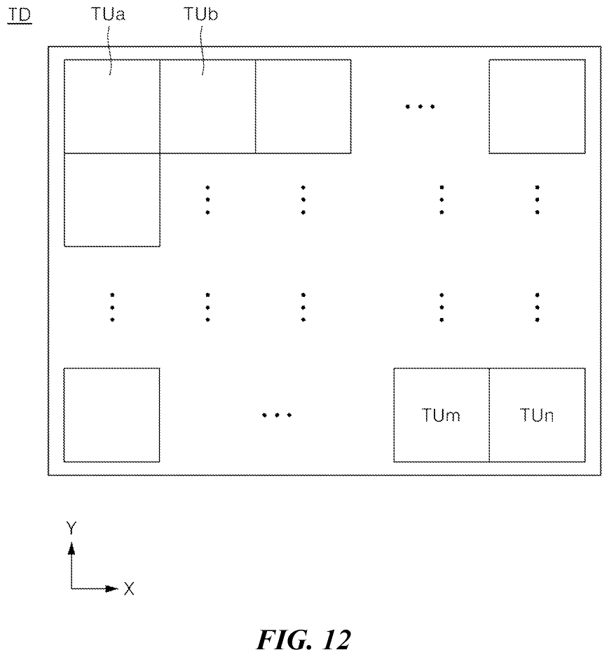

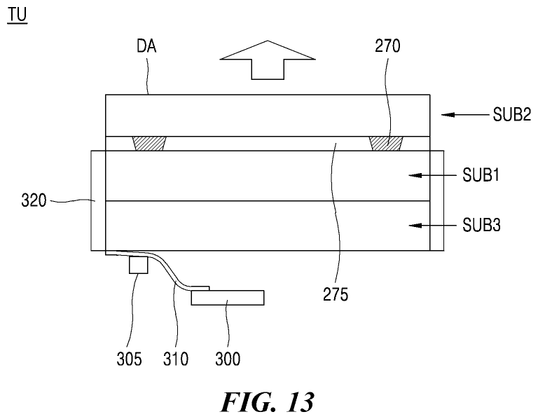

Hereinafter, this will be described with reference to FIG. 12 and FIG. 13.

Referring to FIG. 12, a tiling display device TD may be configured to include a plurality of display panel units TUa, TUb . . . TUm, TUn. In this regard, m and n may be natural numbers. The display panel units TUa, TUb . . . TUm, TUn may be arranged in a first direction X and a second direction Y and may be connected to each other while adjacent display panel units may contact and be connected to each other. In this regard, the first direction X may be a longitudinal direction, while the second direction Y may be a transversal direction.

Referring to FIG. 13, one display panel unit TU among the plurality of display panel units may have a configuration in which the first substrate SUB1 including the thin-film transistor TFT is disposed at a lower level, while the second substrate SUB2 including the light-emitting element is disposed at an upper level, and the bonding pad 270 is disposed therebetween, and the first and second substrates are bonded to each other via the bonding pad 270. In this regard, one surface of the second substrate SUB2 may be a display surface DA from which light emitted from the light-emitting element is emitted to the outside.

A third substrate SUB3 may be attached to a rear surface of the first substrate SUB1. The driver including the printed circuit board 300 connected to the circuit film 310 on which the integrated circuit chip 305 to transmit various signals to each of the sub-pixels including the thin-film transistor TFT or the light-emitting element is mounted may be disposed on a rear surface of the third substrate SUB3. For example, the signals transmitted to the sub-pixels may include high-potential voltage, low-potential voltage, a scan signal, or a data signal. In one implementation of the present disclosure, a configuration in which the driver including the printed circuit board 300 connected to the circuit film 310 on which the integrated circuit chip 305 is mounted is disposed on the rear surface of the third substrate SUB3 is set forth. However, the present disclosure is not limited thereto.

The first substrate SUB1 and the third substrate SUB3 may be electrically connected to each other via a side wiring unit 320. The side wiring unit 320 may include a side wiring for transmitting various signals from the driver disposed on the rear surface of the third substrate SUB3 to the first substrate SUB1 and the second substrate SUB2 and a sealing that protects the side wiring.

Note that, although specific structures of the first substrate SUB1 and the second substrate SUB2 are described herein with reference to the drawings, the described specific structures are only examples, and those skilled in the art could select appropriate specific structures of the first substrate SUB1 and the second substrate SUB2 according to actual needs.

Although the embodiments of the present disclosure have been described in more detail with reference to the accompanying drawings, the present disclosure is not necessarily limited to these embodiments, and may be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be understood that the embodiments described above are not restrictive but illustrative in all respects.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a first substrate including a thin-film transistor;
a second substrate including a light-emitting element; and
a bonding pad disposed between the first substrate and the second substrate, wherein the bonding pad bonds the first substrate and the second substrate to each other and electrically connects the thin-film transistor of the first substrate and the light-emitting element of the second substrate to each other.

2. The display device of claim 1, wherein the first substrate further includes a plurality of reflective electrode patterns overlapping the bonding pad.

3. The display device of claim 1, further comprising a plurality of wiring electrodes electrically connected to the light-emitting element and bonded to the bonding pad.

4. The display device of claim 1, wherein the second substrate further includes:
a self-assembly substrate;
a black bank disposed on the self-assembly substrate;
a planarization layer disposed on the black bank;
an assembly groove in the planarization layer, wherein the light-emitting element is disposed in the assembly groove; and
a pair of assembly electrodes disposed between the black bank and the planarization layer, wherein the pair of assembly electrodes are respectively disposed on both opposing sides of the assembly groove positioned therebetween.

5. The display device of claim 4, wherein the black bank receives therein a condensing lens pattern having a groove shape having a convex surface toward the self-assembly substrate,
wherein a transparent sealant is disposed between the black bank and the assembly electrodes, wherein the transparent sealant fills the condensing lens pattern.

6. The display device of claim 1, wherein the light-emitting element includes:
a nitride semiconductor structure including a first semiconductor layer, an active layer, and a second semiconductor layer;
a first electrode; and
a second electrode,
wherein the nitride semiconductor structure has a trench therein extending through the second semiconductor layer and the active layer so as to expose a portion of a surface of the first semiconductor layer at one side of the nitride semiconductor structure.

7. The display device of claim 6, wherein the first electrode is in the trench and is in contact with the first semiconductor layer, and
wherein the second electrode is in contact with the second semiconductor layer.

8. The display device of claim 7, wherein the bonding pad includes silver paste or an anisotropic conductive film containing a plurality of conductive particles therein,
wherein in a plan view of the display device, the bonding pad has an area larger than an area of the first electrode or the second electrode.

9. The display device of claim 1, wherein the light-emitting element includes a first electrode, a first semiconductor layer, an active layer, a second semiconductor layer, and a second electrode disposed sequentially in a vertical direction,
wherein the first electrode is in contact with the first semiconductor layer, and
wherein the second electrode is in contact with the second semiconductor layer.

10. A display device comprising:
a first substrate including:
a base substrate;
a thin-film transistor disposed on the base substrate;
a first planarization layer disposed on the thin-film transistor;
a first reflective electrode pattern disposed on the first planarization layer;
a second reflective electrode pattern spaced apart from the first reflective electrode pattern; and
a second substrate including:
a self-assembly substrate having an assembly groove defined therein;
a lower wiring electrode disposed on the assembly groove;
a light-emitting element disposed in the assembly groove and having one side contacting the lower wiring electrode;
a protective layer covering the light-emitting element and not covering a portion of a surface of the lower wiring electrode so as to be exposed;
a second wiring electrode including an upper wiring electrode disposed on the protective layer and in contact with the lower wiring electrode; and
a first wiring electrode contacting the other side of the light-emitting element; and
a pair of bonding pads respectively overlapping the first and second reflective electrode patterns of the first substrate, wherein one of the bonding pads electrically connects the second reflective electrode pattern and the first wiring electrode to each other, wherein another of the bonding pads electrically connects the first reflective electrode pattern and the second wiring electrode to each other, wherein the bonding pads bond the first and second substrates to each other.

11. The display device of claim 10, wherein the light-emitting element includes:
a nitride semiconductor structure including a first semiconductor layer, an active layer, and a second semiconductor layer;
a first electrode; and
a second electrode,
wherein the nitride semiconductor structure has a vertical structure in which the first semiconductor layer, the active layer, and the second semiconductor layer are arranged vertically and sequentially.

12. The display device of claim 11, wherein the first electrode is disposed on a rear surface of the first semiconductor layer and is in contact with the first wiring electrode, and
wherein the second electrode is disposed on the second semiconductor layer and is in contact with the lower wiring electrode.

13. The display device of claim 12, wherein each of the bonding pads includes silver paste or an anisotropic conductive film containing a plurality of conductive particles therein,
wherein in a plan view of the display device, each of the bonding pads has an area larger than an area of the first electrode or the second electrode.

14. A method for manufacturing a display device, the method comprising:
providing a first substrate including:
a base substrate;
a thin-film transistor disposed on the base substrate;
a first planarization layer disposed on the thin-film transistor;
a first reflective electrode pattern disposed on the first planarization layer;
a second reflective electrode pattern spaced apart from the first reflective electrode pattern; and
bonding pads respectively overlapping the first and second reflective electrode patterns;
providing a second substrate including:
a self-assembly substrate;
a black bank disposed on the self-assembly substrate;
a planarization layer disposed on the black bank and having an assembly groove defined therein; and
a pair of assembly electrodes disposed between the black bank and the planarization layer and respectively disposed on both opposing sides of the assembly groove disposed therebetween;
aligning a light-emitting element having an electrode with the assembly groove of the second substrate so as to be received in the assembly groove;
forming a protective layer on the self-assembly substrate including the light-emitting element so as to have an opening defined therein exposing a portion of a surface of the electrode of the light-emitting element;
forming a wiring electrode on the protective layer so as to be in contact with the electrode; and
arranging the second substrate including the wiring electrode and the first substrate vertically, and bonding the first substrate and the second substrate to each other via the bonding pads disposed therebetween.

15. The method of claim 14, wherein one surface of each of the bonding pads is in contact with a corresponding one of the first and second reflective electrode patterns, while the other surface opposing the one surface of each of the bonding pads is in contact with the wiring electrode.

16. The method of claim 14, wherein aligning the light-emitting element having the electrode with the assembly groove of the second substrate so as to be received in the assembly groove includes:
inputting the self-assembly substrate into a fluid in which a plurality of light-emitting elements are dispersed;
applying a voltage to the pair of assembly electrodes to generate an electric field around the pair of assembly electrodes; and
moving one light-emitting element among the plurality of light-emitting elements toward the assembly groove under the electric field.

17. A tiling display device comprising a plurality of display units, each of which comprising the display device of claim 1.
